(19) United States
(12) Patent Application Publication
(10) Pub. No.: US 2024/0420913 A1
(43) Pub. Date: Dec. 19, 2024

(54) FABRICATION OF TRANSMISSION TARGET FOR REDUCING EFFECTS OF ELECTRON BEAM DRIFT IN COMPUTED TOMOGRAPHY X-RAY SYSTEM

(71) Applicant: National Technology & Engineering Solutions of Sandia, LLC, Albuquerque, NM (US)

(72) Inventors: Courtney Leigh Hummell Souvinec, Albuquerque, NM (US); Edward Steven Jimenez, Jr., Albuquerque, NM (US); Noelle Collins Rockmore, Albuquerque, NM (US); Gabriella Dalton, Albuquerque, NM (US); Kyle R. Thompson, Albuquerque, NM (US); Amber Lynn Dagel, Lafayette, CO (US); Andrew Lentfer, Albuquerque, NM (US); Matthew Jordan, Albuquerque, NM (US)

(21) Appl. No.: 18/816,042

(22) Filed: Aug. 27, 2024

Related U.S. Application Data
(63) Continuation-in-part of application No. 18/226,510, filed on Jul. 26, 2023.
(60) Provisional application No. 63/392,567, filed on Jul. 27, 2022.

(51) Int. Cl. H01J 35/08; C23C 14/02; C23C 14/16; C23C 14/18; C23C 16/02; C23C 16/06; C23C 16/455; G01N 23/046

(52) U.S. Cl. CPC H01J 35/116; C23C 14/021; C23C 14/16; C23C 14/18; C23C 16/0245; C23C 16/06; C23C 16/45555; G01N 23/046; H01J 2235/081

(57) ABSTRACT

A method of fabricating a transmission target for an X-ray system is provided. The method includes forming a substrate and etching at least one via in the substrate. The method includes depositing a layer of seed metal on the surface of the substrate. The method includes filling the vias with a target metal to form target metal blocks.

### RELATED APPLICATIONS

This application is a continuation-in-part and claims priority to U.S. application Ser. No. 18/226,510, filed on Jul. 26, 2023, and entitled MULTI-METAL PATTERNED ANODE FOR COMPUTED TOMOGRAPHY X-RAY SYSTEMS, the entirety of which is incorporated herein by reference, which claims priority from provisional application No. 63/392,567, filed Jul. 27, 2022, entitled “MULTI-METAL PATTERNED X-RAY TRANSMISSION TARGET AND FABRICATION”.

### STATEMENT OF GOVERNMENT INTEREST

This invention was made with United States Government support under Contract No. DE-NA0003525 between National Technology & Engineering Solutions of Sandia, LLC and the United States Department of Energy. The United States Government has certain rights in this invention.

### BACKGROUND

### 1. Field

The disclosure relates generally to Computed Tomography (CT) X-ray systems, and more specifically to fabrication of a transmission target for reducing effects of electron beam drift in X-ray systems.

### 2. Description of the Related Art

CT X-ray systems are used in identification and analysis of materials. Conventional detectors or detector arrays in CT systems measure the total intensity of X-rays impinging on the detector after the X-rays interact with a sample being analyzed. The total intensity or ‘count’ of X-rays at the detector is compared to the ‘count’ of X-rays generated from the target, and the difference in ‘count’ indicates the material composition of the sample.

In some X-ray tubes, an electron beam is generated by applying high voltage to accelerate electrons from a cathode towards an anode. The electron beam is focused on a transmission target and the electron interaction with the target atoms generates X-rays used for imaging.

In X-ray tubes, electron beam drift occurs due to several factors, with voltage fluctuations, mechanical vibrations, fluctuations in electric and magnetic fields, and thermal vibrations being significant contributors. The electron beam drift refers to the movement or displacement of the electron beam from its intended path or focal point, causing distortion in CT data. Variations in the applied voltage can cause fluctuations in the electron beam's trajectory. If the voltage fluctuates, it can affect the strength and direction of electromagnetic fields that guide the electrons, leading to a beam drift. Also, mechanical vibrations, whether from the equipment itself or external sources, can disrupt the stability of the electron beam's path. Vibrations introduce movement or shifts in the components of the X-ray tube, impacting the precise positioning of the electron beam. This movement can result in the electron beam deviating from its ideal focal point, causing blurring or distortion in the X-ray images obtained.

### SUMMARY

An illustrative embodiment provides a method of fabricating a transmission target for an X-ray system. The method comprises forming a substrate and etching at least one via in the substrate. The method comprises depositing a layer of seed metal on a top surface of the substrate. The method comprises filling the vias with a target metal to form target metal blocks.

In an illustrative embodiment, the substrate is made of silicon, silicon carbide, beryllium, or diamond, and the layer of seed metal is a layer of copper, gold, silver, platinum, aluminum or chromium. The target metal is copper, gold, molybdenum, silver, aluminum, tungsten, or chromium.

Another illustrative embodiment provides a method of fabricating a transmission target for an X-ray system. The method comprises forming a first substrate and etching at least one via in the first substrate. The method comprises forming a second substrate and depositing a layer of seed metal on a top surface of the second substrate. The method comprises placing the first substrate on the second surface with the vias facing down toward the second substrate. The method comprises removing a portion of the first surface to expose the vias in the first substrate. The method comprises filling the vias with a target metal to form target metal blocks in the first substrate.

Another illustrative embodiment provides a method of fabricating a transmission target for an X-ray system. The method comprises forming a first substrate and a second substrate. The method comprises depositing a layer of seed metal on the top surface of the second substrate and bonding the first substrate onto the second surface. The method comprises etching at least one via in the first substrate. The method comprises filling the vias with a target metal to form target metal blocks in the first substrate.

Another illustrative embodiment provides an X-ray system. The system comprises a cathode configured to emit electrons. The system comprises an anode positioned in a line of the emitted electrons and configured to pass through at least some of the emitted electrons striking the anode. The system comprises a transmission target positioned in the line of emitted electrons passing through the anode and configured to produce X-ray beams responsive to the electrons striking the transmission target. The transmission target comprises a substrate and a target metal block embedded in the substrate, wherein the width of the target metal block is less than the width of the substrate. The system comprises an X-ray detector configured to detect the X-rays produced by the transmission target and generate corresponding electrical signals.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 depicts an X-ray system in accordance with an illustrative embodiment;

FIG. 2 illustrates a transmission target in accordance with an illustrative embodiment;

FIG. 3 illustrates mitigation of the effects of electron beam drift by a target metal block in accordance with an illustrative embodiment;

FIGS. 4A and 4B illustrate effects of electron beam drift in a conventional CT X-ray system;

FIGS. 5A-5C illustrate a process of fabricating a transmission target for an X-ray system in accordance with an illustrative embodiment;

FIG. 6 shows an image of a transmission target fabricated in accordance with an illustrative embodiment;

FIGS. 7A-7E illustrate a process of fabricating a transmission target in accordance with another illustrative embodiment;

FIGS. 8A-8E illustrate a process of fabricating a transmission target in accordance with another illustrative embodiment; and

FIGS. 9-11 depict flowcharts illustrating methods of fabricating a transmission target for an X-ray system.

### DETAILED DESCRIPTION

The illustrative embodiments provide a transmission target for an X-ray system. The transmission target mitigates the effects of electron beam drift or shift which can be caused, for example, by variations in the applied voltage in the X-ray system, variations in electric or magnetic field, mechanical vibrations or thermal vibrations in the X-ray system.

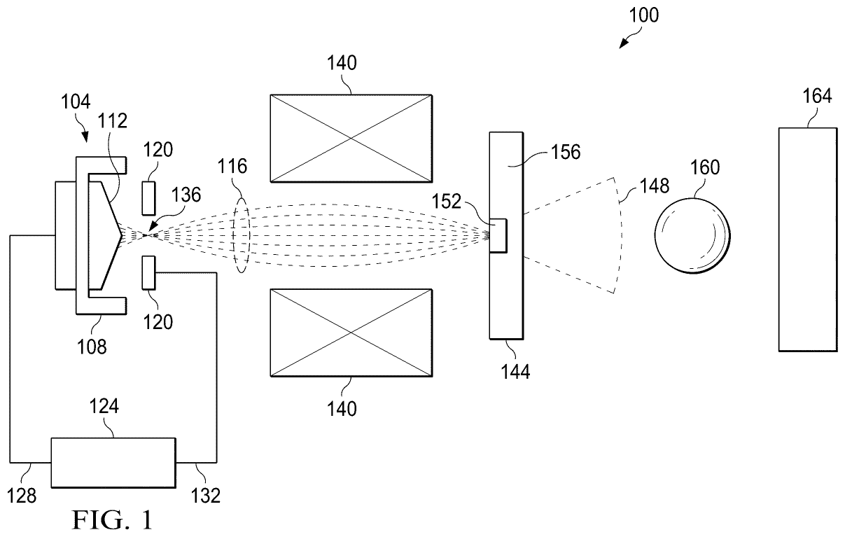

FIG. 1 depicts an X-ray system 100 in accordance with an illustrative embodiment. In some embodiments, system 100 may be implemented as an X-ray tube. System 100 includes cathode 104 configured to emit electrons. Cathode 104 includes filament 112 which is a wire made of tungsten or another high-melting-point material. Cathode 104 may include focusing cup 108 configured to shape and direct the emitted electrons into electron beam 116. Focusing cup 108 prevents electron beam 116 from dispersing.

System 100 includes anode 120 which is placed in the line of electron beam 116. In an example embodiment, anode 120 is made of tungsten. System 100 includes power supply 124 configured to apply a DC voltage between cathode 104 and anode 120. Power supply 124 includes first terminal 128 electrically connected to cathode 104 and includes second terminal 132 electrically connected to anode 120. Power supply 124, may for example, be a switch mode regulated converter which provides a regulated DC voltage. In some example embodiments, power supply 124 is configured to output a regulated DC voltage in a range of OV to several hundred KV.

When a high voltage is applied between cathode 104 and anode 120, a strong electric field is established between cathode 104 and anode 120. As a result, current flows through filament 112, causing it to heat up and emit electrons through a process called thermionic emission. The temperature of filament 112 may be controlled to ensure a consistent emission of electrons. Focusing cup 112 shapes and directs the emitted electrons into electron beam 116 pointed at anode 120. Electron beam 116 accelerates towards anode 120 and passes through window 136 of anode 120.

System 100 may include electromagnetic lens 140 to control and focus electron beam 116. The primary function of electromagnetic lens 136 is to shape electron beam 116, restricting its size and improving spatial coherence. By applying varying magnetic fields to specific regions along the path of electron beam 116, electromagnetic lens 136 manipulates the trajectory of electron beam 116. This manipulation allows for the precise focusing and narrowing of electron beam 116.

System 100 includes transmission target 144 which is a specialized component configured to produce X-rays. The high-speed electrons in electron beam 116 strike transmission target 144, causing the electrons to rapidly decelerate and transfer energy to the material of transmission target 144, resulting in the emission of X-rays 148 which are used for imaging purposes.

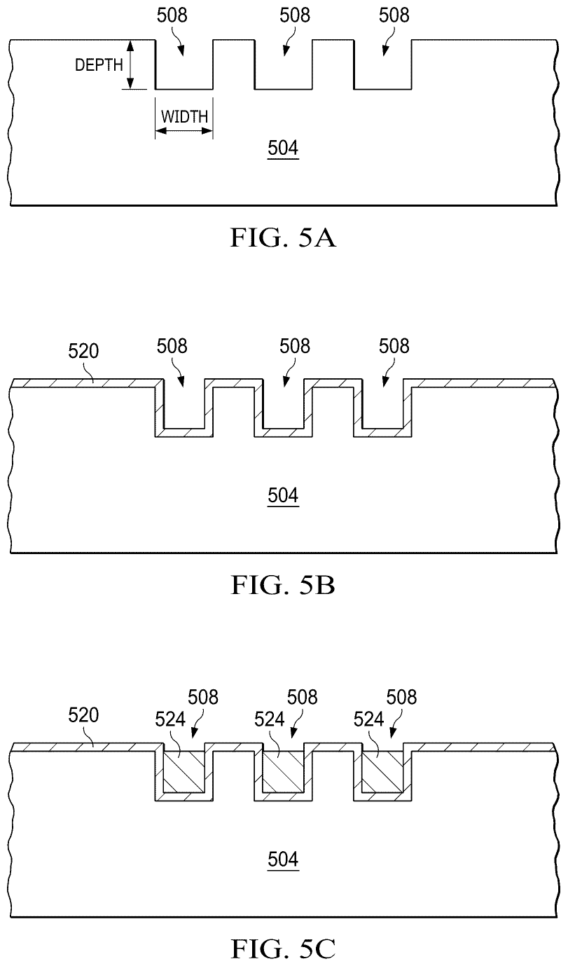

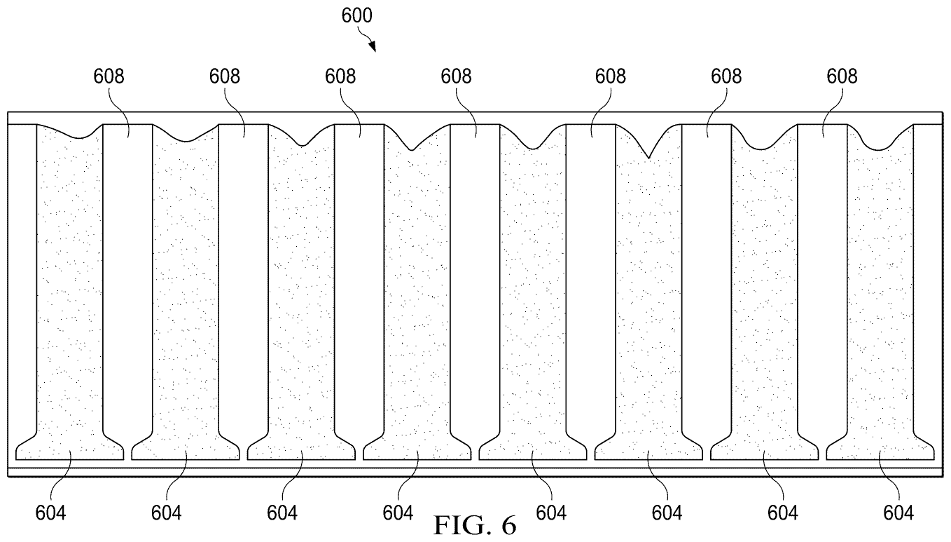

In an illustrative embodiment, transmission target 144 includes a small target metal block 152 (not drawn to scale in FIG. 1) embedded in substrate 156. Target metal block 152 is described in more detail with reference to FIGS. 5A-5C.

System 100 may be used to image or analyze object 160. Object 160 is positioned between transmission target 144 and X-ray detector 164. Object 160 can be a biological tissue (e.g., medical imaging), various materials (e.g., industrial inspection), or any other item of interest. When X-rays 148 pass through object 160, they interact differently depending on object 160's composition and density. Some X-rays 148 are absorbed by object 160, some are scattered, and some pass-through object 160 without any change in their path. X-ray detector 164, which is placed opposite the X-ray source (e.g., transmission target 144), captures the X-rays that pass-through object 160. X-ray detector 166 is a specialized device that measures and quantifies the intensity of X-rays captured by X-ray detector 164.

In some example embodiments, X-ray detector 164 is implemented as a complementary metal-oxide-semiconductor (CMOS) detector. The CMOS detector includes an array of pixels, each consisting of a photodiode and a transistor (not illustrated in FIG. 1). As X-rays 148 interact with the photodiode, electrical charges are produced which are amplified and read out by the transistors. CMOS detectors offer high-speed readout, low noise, and high image quality. In other example embodiments, X-ray detector 164 is implemented as a scintillator-type detector or a Cadmium Telluride (CdTe) detector. The data collected by X-ray detector 164 is processed by a computer to reconstruct a two-dimensional or a three-dimensional image. The contrast within the image represents the varying attenuation of X-rays as they pass through different parts of object 160, revealing its internal structures, densities, and any abnormalities.

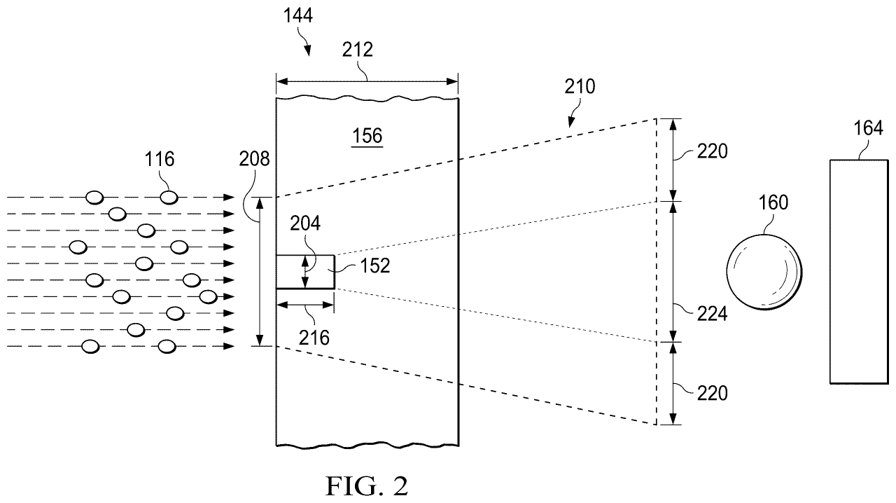

FIG. 2 illustrates transmission target 144 in accordance with an illustrative embodiment. Transmission target 144 produces X-rays which are used to analyze or image object 160. Transmission target 144 is a component of an X-ray system or an X-ray tube.

Transmission target 144 comprises substrate 156 which can be formed using, for example, beryllium, silicon, silicon carbide, diamond, molybdenum, or aluminum. The selection of a material for substrate 156 is based on the material's characteristics, including density, X-ray transmission and thermal conductivity. In some embodiments, the substrate material is selected for its low density, X-ray transmission and high thermal conductivity.

Transmission target 144 comprises a small target metal block 152 (not drawn to scale in FIG. 2) embedded in substrate 156. Target metal block 152 can be made using a target metal such as, for example, copper, tungsten, gold, molybdenum, silver or chromium. The selection of the target metal for target metal block 152 depends on object 160 being analyzed and desired X-ray energy used to analyze object 160. In some embodiments, the target metal for target metal block 152 is selected for its high melting point.

To eliminate the effects of beam drift of electron beam 116, target width 204 of target metal block 152 is less than electron beam width 208 on substrate 156. As such, target metal block 152 is narrower than X-rays 210 produced by entire substrate 156 of transmission target 144. As illustrated in FIG. 2, X-rays 210 produced by transmission target 144 comprise an inner narrow band 224 which is produced by target metal block 152 and outer bands 220 produced by substrate 156.

In an illustrative embodiment, the material for target metal block 152 is selected for its high energy X-ray producing characteristics while the material for substrate 156 is selected for its low-energy or no X-ray producing characteristics. Thus, by measuring and quantifying the X-ray energy densities of X-rays 210, inner band 224 and outer bands 220 can be identified. As such, the X-rays produced by target metal block 152 can be distinguished from X-rays produced by substrate 156.

In an illustrative embodiment, target width 204 of target metal block 152 is around 33 microns, and target thickness 216 of target block 152 is around 20 microns. In an illustrative embodiment, substrate thickness 212 of substrate 156 is around 300 microns.

As illustrated in FIG. 2, object 160 is positioned between transmission target 144 which produces X-rays 210 and X-ray detector 164. Object 160 can be a biological tissue (e.g., medical imaging), various materials (e.g., industrial inspection), or any other item of interest. When X-rays 210 pass through object 160, they interact differently depending on object 160's composition and density. Some X-rays 210 are absorbed by object 160, some are scattered, and some pass-through object 160 without any change in their path. X-ray detector 164, which is placed opposite transmission target 144, captures the X-rays that pass-through object 160. X-ray detector 164 measures and quantifies the intensity of X-rays captured by X-ray detector 164. The data collected by X-ray detector 164 is processed to reconstruct a two-dimensional or a three-dimensional image. This image represents the varying attenuation of X-rays as they passed through different parts of object 160, revealing its internal structures, densities, and any abnormalities.

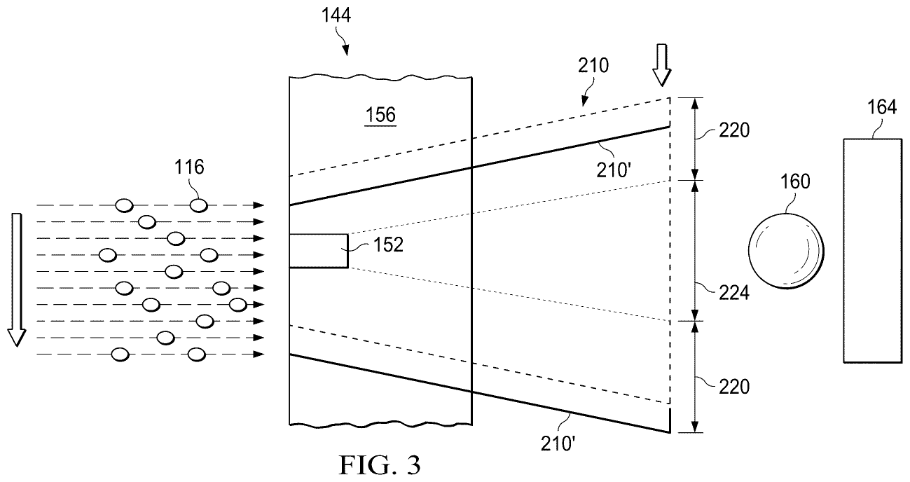

FIG. 3 illustrates the mitigation of the effects of electron beam drift or shift by target metal block 152 which is embedded in a larger transmission target 144. Due to voltage fluctuations, mechanical vibration or thermal fluctuations, electron beam 116 drifts downward relative to transmission target 144. As a result, X-rays 210 produced by transmission target 144 also drifts downward. The downward drifted X-rays are illustrated by solid lines as X-rays 210′ relative to X-rays 210. While the entire X-ray beam 210 has shifted to 210′, the high energy region indicated by inner band 224 that corresponds to the X-rays produced from target block 152 does not move spatially relative to sample 160 being imaged. Outer band 220 portions of the X-rays that have moved spatially do not contribute to the characterization of sample 160 and thus the electron beam drift is not observed in the data output.

In FIG. 3, X-rays produced by the smaller target metal block 152 are represented by inner band 224 which is located within outer band 220. Although the overall X-rays 210′ produced by transmission target 144 has shifted downward relative to object 160, X-rays 224 produced by the smaller target metal block 152 do not shift downward relative to object 160. As such, X-rays produced by the smaller target metal block 152 can reliably and consistently strike and pass through object 160 without drift of the angle or position of approach. X-ray detector 164 measures and quantifies the intensity of X-rays which pass through object 160. The data collected by X-ray detector 164 is used to reconstruct a two-dimensional or a three-dimensional image. This image represents the varying attenuation of X-rays as they pass through different parts of object 160, revealing its internal structures, densities, and any abnormalities.

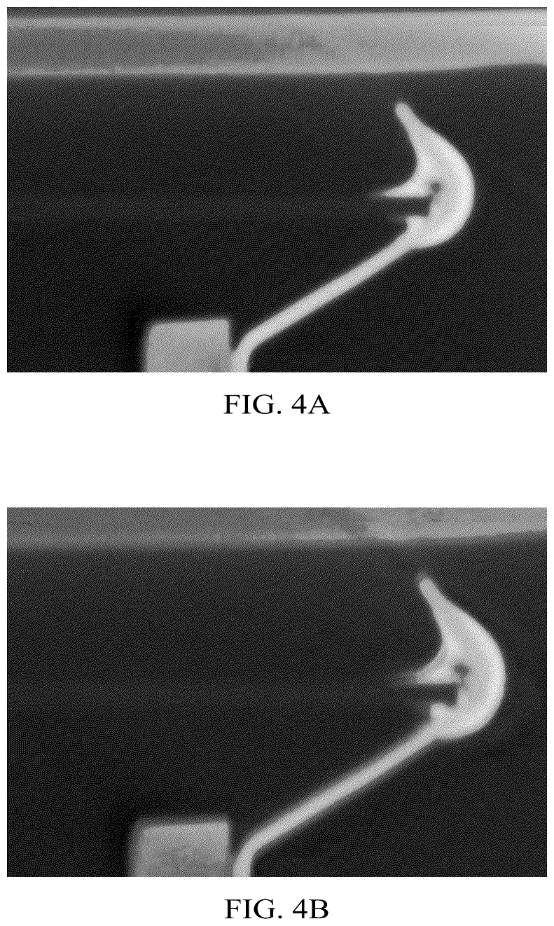

FIGS. 4A and 4B illustrate effects of drift of the electron beam in a conventional CT X-ray system. FIG. 4B shows a reconstructed CT image cross section of a weld in which the electron beam drifted during a lengthy acquisition and resulted in a blurred image. Due to the poor image quality, the measurement had to be retaken until it was successful without suffering from electron beam drift and yielded the image in FIG. 4A.

FIGS. 5A-5C illustrate a process of fabricating multiple transmission targets for X-ray systems in accordance with an illustrative embodiment. Each target can be diced out or singulated after the fabrication or the targets can be spaced far enough from one another such that one is exposed by the electron beam at a time during operation. Substrate 504 is formed using, for example, silicon, silicon carbide, beryllium, or diamond (FIG. 5A). The selection of the material for substrate 504 is based on the material's characteristics including density, X-ray transmission, and thermal conductivity. Vias 508 are etched in substrate 504. In some example embodiments, vias 508 are etched using the BOSCH etch process which is used in microfabrication to create high aspect ratio structures in silicon-based substrates. In some embodiments, each via 508 is 20 microns deep and between 10 to 20 microns wide.

Next, a layer of seed metal 520 is deposited conformally on top surface of substrate 504 (FIG. 5B). In some example embodiments, atomic layer deposition (ALD) technique is used to deposit the layer of seed metal 520 on top surface of substrate 504. ALD is a thin film deposition technique used in semiconductor manufacturing to create extremely precise and controlled layers of materials at an atomic level. ALD allows for the deposition of thin films with exceptional uniformity, thickness control, and conformality on complex surfaces. In some embodiments, seed metal 520 is platinum but can be any other suitable metal such as gold, silver, copper, or aluminum.

Finally, target metal blocks 524 are formed by filling vias 508 with a selected target metal to create the transmission target (FIG. 5C). In an example embodiment, target metal blocks 524 are formed by filling vias 508 with copper using an electroplating process. Although, three target metal blocks 524 are formed in substrate 504, the process may be utilized to form any number of target metal blocks 524 in substrate 504. Each target block 524 can be diced out or singulated after the fabrication.

FIG. 6 shows an image of example transmission targets 600 fabricated in accordance with another illustrative embodiment. In this example, a total of eight copper target metal blocks 604 are formed in silicon substrate 608. In this example, eight copper target blocks 604 are spaced very close to one another. In other embodiments, target blocks are spaced much farther apart and then diced out or singulated.

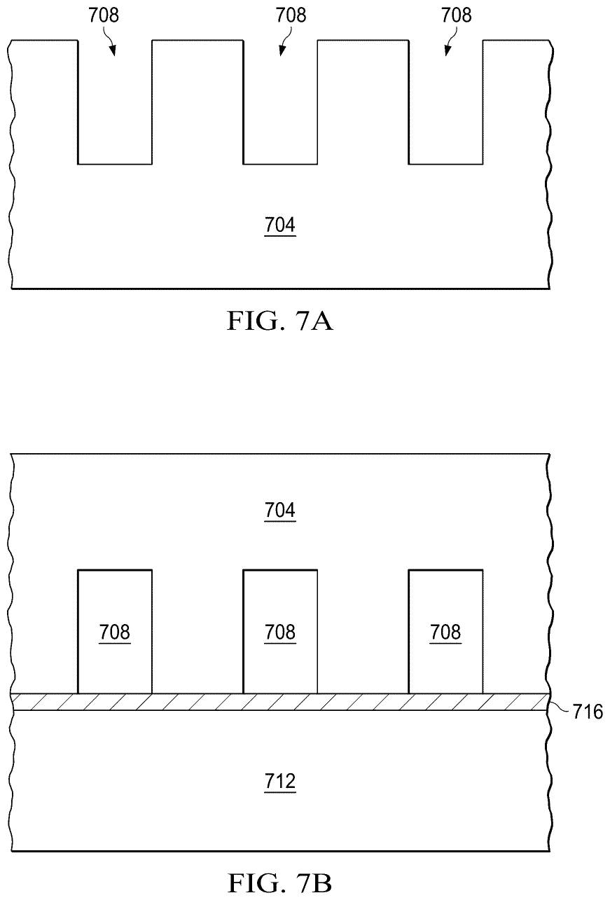

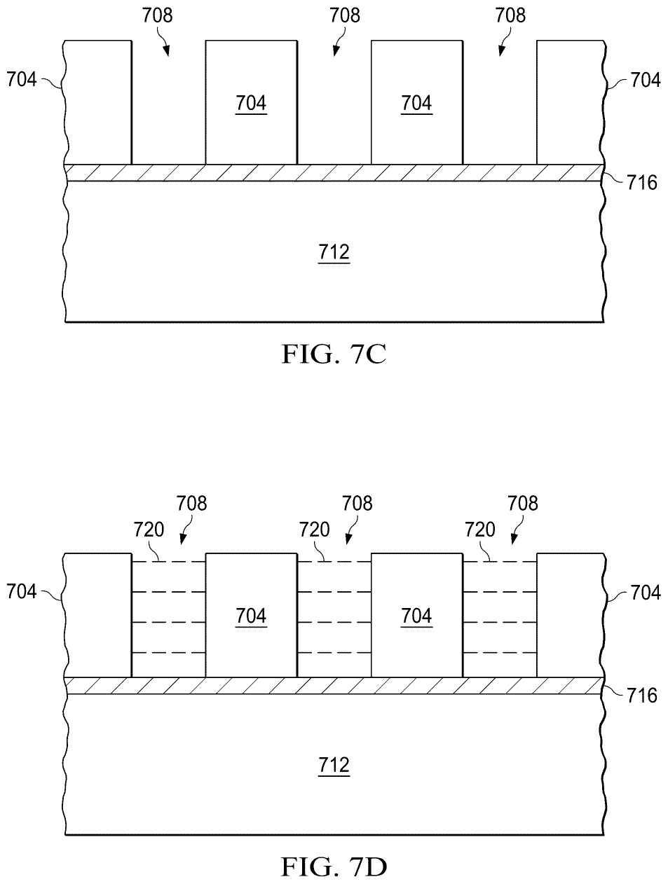

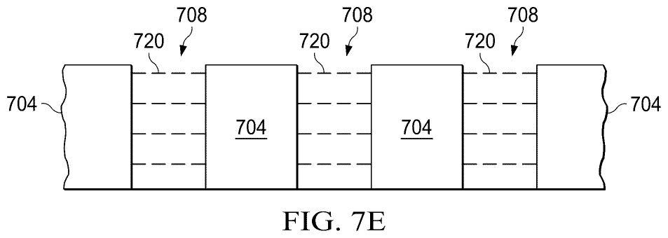

FIGS. 7A-7E illustrate a process of fabricating multiple transmission targets in accordance with another illustrative embodiment. A first substrate 704 is formed (FIG. 7A). First substrate 704 can, for example, be formed using silicon, silicon carbide or diamond. Next, vias 708 are etched in first substrate 704. In some example embodiments, vias 708 are etched using the BOSCH etch process.

Next, second substrate 712 is formed and a layer of seed metal 716 is uniformly deposited on top surface of second substrate 712 (FIG. 7B). In some example embodiments, evaporation or other physical vapor deposition (PVD) is used to uniformly deposit the layer of seed metal 716 on top surface of second substrate 712. First and second substrates 704 and 712 can be formed using same or different materials. First substrate 704 is then flipped and placed on the layer of seed metal 716, and first substrate 704 is bonded with the layer of seed metal 716. At this stage of the process, first and second substrates 704 and 712 are separated by the layer of seed metal 716 with vias 708 facing down.

Next, a portion of first substrate 704 is removed by etching or back-grinding to expose or open vias 708 (FIG. 7C). Finally, the transmission targets are created by filling vias 708 with a target metal such as, for example, copper, aluminum, gold or silver to form target blocks 720 (FIG. 7D). In some example embodiments, second substrate 712 and seed metal 716 can be optionally removed by etching or grinding (FIG. 7E), thus leaving substrate 704 with embedded target metal blocks 720 exposed from both sides.

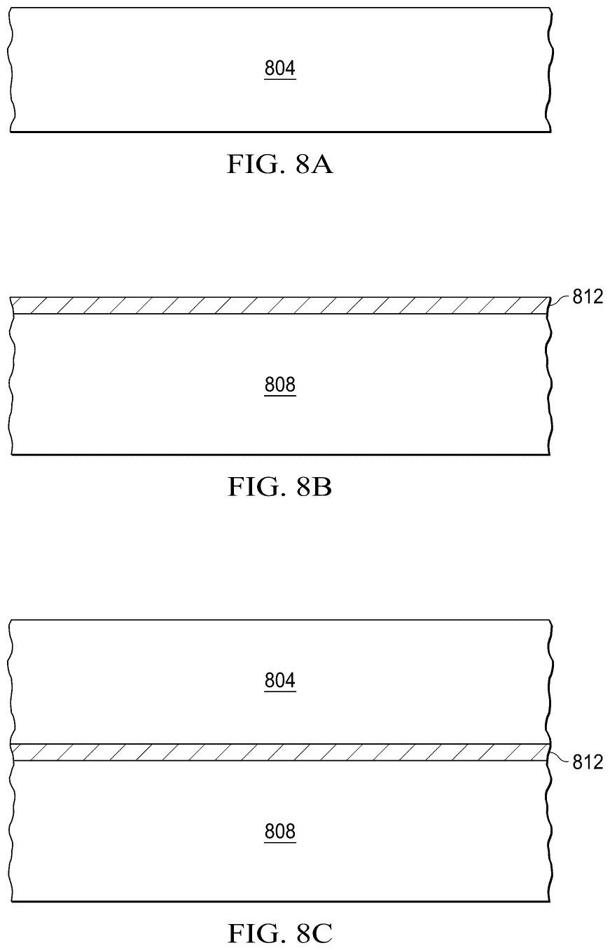

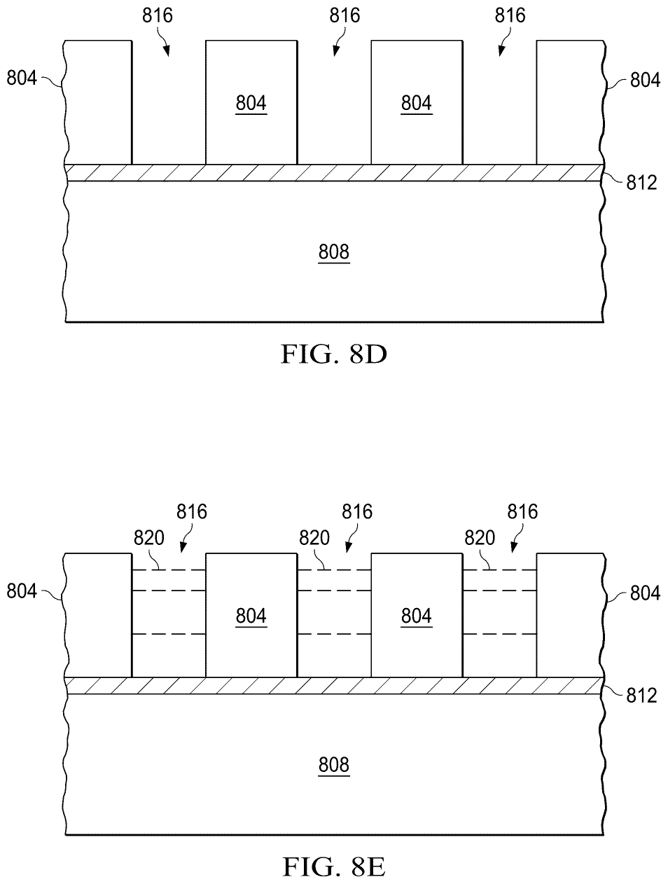

FIGS. 8A-8E illustrate a process of fabricating transmission targets in accordance with another illustrative embodiment. First substrate 804 is formed (FIG. 8A). First substrate 804 can, for example, be formed from silicon, silicon carbide, beryllium, or diamond. Next, second substrate 808 is formed (FIG. 8B). Second substrate 808 can be formed of the same or a different material used in first substrate 804. A layer of seed metal 812 is deposited uniformly on top surface of second substrate 808. In some example embodiments, evaporation or other physical vapor deposition (PVD) is used to deposit the layer of seed metal 812.

Next, first substrate 804 is placed over second substrate 808 (FIG. 8C), and first substrate 804 is bonded with the layer of seed metal 812. Vias 816 are etched in first substrate 804 (FIG. 8D). In some example embodiments, vias 816 are etched using the BOSCH etch process.

Next, target metal blocks 820 are formed by filling vias 816 with a target metal such as copper, aluminum, molybdenum, tungsten, silver, or gold (FIG. 8E). Second substrate 808 can thereafter be optionally removed by etching or grinding.

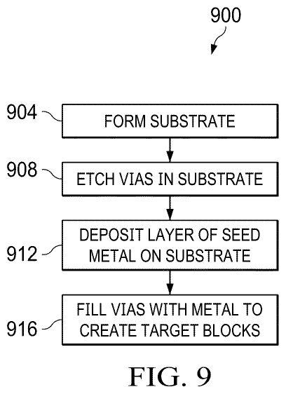

FIG. 9 depicts a flowchart illustrating a method of fabricating a transmission target for an X-ray system in accordance with an illustrative embodiment. Process 900 starts with forming a substrate (step 904). The substrate may, for example, be formed by a layer of diamond, beryllium, silicon, or silicon carbide. The choice of substrate material depends on the specific requirements, including density, X-ray transmission, thermal conductivity, coefficient of thermal expansion (CTE), and overall cost.

Vias are etched in the substrate (step 908). In some example embodiments, the vias are etched using the BOSCH etch process which is used in microfabrication to create high aspect ratio structures in silicon-based substrates. A layer of seed metal is deposited uniformly on the top surface of the substrate (step 912). In some example embodiments, atomic layer deposition (ALD) technique is used to deposit the layer of seed metal on the substrate. ALD allows for the deposition of thin films with exceptional uniformity, thickness control, and conformality on complex surfaces. In an example embodiment, the seed metal is platinum but can be any other suitable metal such as gold, silver, chromium, molybdenum, copper, or aluminum.

The transmission target is then created by forming target metal blocks by filling the vias with a selected target metal (step 916). In an example embodiment, the target metal blocks are formed by filling the vias with copper, gold, silver, aluminum, or chromium using an electroplating process.

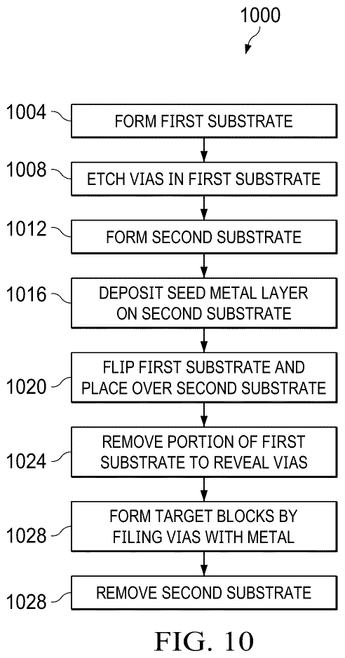

FIG. 10 depicts a flowchart illustrating a method of fabricating a transmission target for an X-ray system in accordance with another illustrative embodiment. Process 1000 starts with forming a first substrate (step 1004). The first substrate may, for example, be formed by a layer of diamond, beryllium, silicon, or silicon carbide. Vias are etched in the first substrate (step 1008). In some example embodiments, the vias are etched using the BOSCH etch process.

A second substrate is formed (step 1012). The first and second substrates may be formed using the same or different materials. A layer of seed metal is uniformly deposited on the top surface of second substrate (step 1016). In some example embodiments, PVD technique is used to uniformly deposit the layer of seed metal on the second substrate.

The first substrate is then flipped and placed on the layer of seed metal, and the first substrate is bonded with the layer of seed metal (step 1020). At this stage of the process, the first and second substrates are separated by the layer of seed metal with the vias facing down.

Next, a portion of the first substrate is removed by etching or back-grinding to expose or open the vias (step 1024). Next, the transmission target is created by filling the vias with a target metal such as, for example, copper, aluminum, gold, silver or molybdenum to form target blocks (step 1028). In some example embodiments, the second substrate can be optionally removed by etching or grinding (step 1032), thus leaving the first substrate with the target blocks embedded.

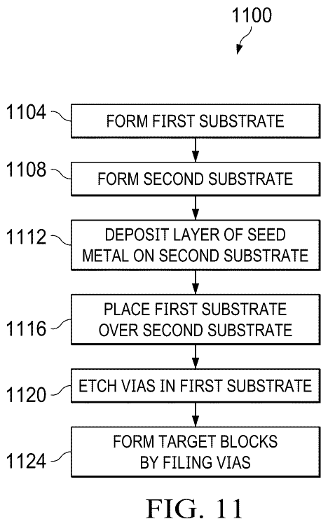

FIG. 11 depicts a flowchart illustrating a method of fabricating a transmission target for an X-ray system in accordance with another illustrative embodiment. Process 1100 starts with forming a first substrate (step 1104). The first substrate may, for example, be formed by a layer of diamond, beryllium, silicon, or silicon carbide.

A second substrate is formed (step 1108). The second substrate can be formed using the same or a different material used in the first substrate. A layer of seed metal is deposited uniformly on the top surface of the second substrate (step 1112). In some example embodiments, PVD technique is used to deposit the layer of seed metal on the second substrate.

The first substrate is placed over the second substrate (step 1116) and is bonded with the second substrate. Next, vias are etched in the first substrate (step 1120). In some example embodiments, the vias are etched using the BOSCH etch process. Next, target blocks are formed by filling the vias with a target metal such as copper (step 1124). The second substrate can be optionally removed by etching or grinding (not shown in FIG. 11).

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component. Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A method of fabricating a transmission target for an X-ray system, comprising:
forming a substrate;
etching at least one via in the substrate;
depositing a layer of seed metal on a top surface of the substrate; and
filling the vias with a target metal to form target metal blocks.

2. The method of claim 1, wherein the vias are etched in the substrate using a BOSCH process.

3. The method of claim 1, wherein the layer of seed metal is deposited using an atomic layer deposition process or a physical deposition process.

4. The method of claim 1, wherein the substrate is made of silicon, silicon carbide, beryllium, or diamond.

5. The method of claim 1, wherein the layer of seed metal is a layer of copper, gold, silver, platinum, aluminum or chromium.

6. The method of claim 1, wherein the target metal is copper, gold, molybdenum, silver, aluminum, tungsten, or chromium.

7. A method of fabricating a transmission target for an X-ray system, comprising:
forming a first substrate;
etching at least one via in the first substrate;
forming a second substrate;
depositing a layer of seed metal on a top surface of the second substrate;
placing the first substrate on the second surface with the vias facing down toward the second substrate;
removing a portion of the first surface to expose the vias in the first substrate; and
filling the vias with a target metal to form target metal blocks in the first substrate.

8. The method of claim 7, further comprising bonding the first substrate with the layer of seed metal on the second substrate.

9. The method of claim 7, further comprising removing the second substrate.

10. The method of claim 7, wherein the first substrate is made of silicon, silicon carbide, beryllium, or diamond.

11. The method of claim 7, wherein the second substrate is made of silicon, silicon carbide, beryllium, or diamond.

12. The method of claim 7, wherein the vias are etched in the first substrate using a BOSCH process.

13. The method of claim 7, wherein the layer of seed metal is deposited on the surface of the second substrate using an atomic layer deposition process or a physical vapor deposition process.

14. The method of claim 7, wherein the layer of seed metal is a layer of copper, gold, platinum, silver, aluminum or chromium.

15. The method of claim 7, wherein the target metal is copper, gold, molybdenum, silver, aluminum, tungsten, or chromium.

16. A method of fabricating a transmission target for an X-ray system, comprising:
forming a first substrate;
forming a second substrate;
depositing a layer of seed metal on the top surface of the second substrate;
bonding the first substrate onto the second surface etching at least one via in the first substrate; and
filling the vias with a target metal to form target metal blocks in the first substrate.

17. The method of claim 16, further comprising removing the second substrate.

18. The method of claim 16, further comprising bonding the first substrate with the layer of seed metal on the second substrate.

19. An X-ray system, comprising:
a cathode configured to emit electrons;
an anode positioned in a line of the emitted electrons and configured to pass through at least some of the emitted electrons striking the anode;
a transmission target positioned in the line of emitted electrons passing through the anode and configured to produce X-ray beams responsive to the electrons striking the transmission target, the transmission target comprising:
a substrate; and
a target metal block embedded in the substrate, wherein the width of the target metal block is less than the width of the substrate.

20. The X-ray system of claim 19, further comprising an X-ray detector configured to detect the X-rays produced by the transmission target and generate corresponding electrical signals.

21. The X-ray system of claim 19, wherein the target metal block comprises a via filled with a target metal.
